(19) United States
(12) Patent Application Publication
(10) Pub. No.: US 2024/0154590 A1
(43) Pub. Date: May 9, 2024

(54) CASCODE AMPLIFIER WITH IMPROVED AMPLIFICATION CHARACTERISTICS

(71) Applicant: SAMSUNG ELECTRONICS CO., LTD., SUWON-Si (KR)

(72) Inventors: JOONGGEUN LEE, Suwon-si (KR); JEONGYEOL BAE, Suwon-si (KR); JONGSOO LEE, Suwon-si (KR); SANGMIN YOO, Suwon-si (KR)

(21) Appl. No.: 18/343,367

(22) Filed: Jun. 28, 2023

(30) Foreign Application Priority Data
Nov. 9, 2022 (KR) 10-2022-0148438

(51) Int. Cl. H03F 3/45; H03F 1/32

(52) U.S. Cl. CPC H03F 3/45264; H03F 1/3211; H03F 2200/297; H03F 2200/451

(57) ABSTRACT

Disclosed is an amplifier including a first transistor and a second transistor to which differential input signals are applied to gate terminals thereof, respectively, a second transistor having a first end connected to the first transistor, a gate terminal receiving a first bias signal, and a second end outputting a first differential output signal of a differential output signal pair, a fourth transistor having a first end connected to the second transistor, a gate terminal receiving a second bias signal, and having a second end outputting the a second differential output signal, and a pair of capacitors coupled to the second transistor and the fourth transistor, and having a cross-coupled structure with respect to each other.

### CROSS-REFERENCE TO RELATED APPLICATIONS

This application claims priority under 35 U.S.C. § 119 to Korean Patent Application No. 10-2022-0148438 filed on Nov. 9, 2022, in the Korean Intellectual Property Office, the disclosures of which are incorporated by reference herein in their entireties.

### TECHNICAL FIELD

Embodiments of the present disclosure relate to a cascode amplifier with improved amplification characteristics.

### DISCUSSION OF RELATED ART

A cascode amplifier comprising field effect transistors (FETs) may be a two stage amplifier constructed with a common-source (CS) FET feeding into a common-gate (CAS) FET. A cascode amplifier may secure a voltage headroom of an output and amplify a signal to have a power level desired by a designer. (Voltage headroom may be understood as an amount by which the voltage-handling capability of the amplifier is permitted to exceed a nominal level while satisfactory operation is maintained.)

One way for a cascode amplifier to secure a desired voltage headroom is to design a size of the common-gate transistor to be greater than a size of the common-source transistor, in which case the linearity of the output may be improved. However, as the size of the common-gate transistor is increased to secure the voltage headroom, negative impedance is generated, resulting in the possibility of oscillation. As a result, a trade-off may exist in a cascode amplifier between the amount of voltage headroom attainable and the probability of oscillation.

### SUMMARY

Embodiments of the present disclosure provide a cascode amplifier having improved amplification characteristics even when a size of the common-gate transistor exceeds that of the common-source transistor.

According to an embodiment of the present disclosure, an amplifier includes a first transistor and a second transistor to which differential input signals of a differential input signal pair are applied to gate terminals thereof, respectively, a third transistor having a first end connected to the first transistor, a gate terminal receiving a first bias signal, and a second end outputting a first differential output signal of a differential output signal pair, a fourth transistor having a first end connected to the second transistor, a gate terminal receiving a second bias signal, and a second end outputting a second differential output signal of the differential output signal pair, and a pair of capacitors coupled to the third and fourth transistors, and having a cross-coupled structure with respect to each other.

In various embodiments:

The pair of capacitors may include a first capacitor having a first end connected to the second end of the fourth transistor and a second end connected to the first end of the third transistor, and a second capacitor having a first end connected to the second end of the third transistor and a second end connected to the first end of the fourth transistor.

The first capacitor may cancel a parasitic capacitance component of the fourth transistor, and the second capacitor may cancel a parasitic capacitance component of the second transistor.

A capacitance of the first capacitor may depend on a size of the fourth transistor, and a capacitance of the second capacitor may depend on a size of the second transistor.

A resistance component of an output impedance defined at the second end of the third transistor and the second end of the fourth transistor may have a positive value.

The pair of capacitors may cancel parasitic capacitance components when the first through fourth transistors are turned on, and also when they are turned off.

The first through fourth transistors may be NMOS transistors.

A size of the third transistor may be greater than that of the first transistor, and a size of the fourth transistor may be greater than that of the second transistor.

A current flowing through the first capacitor and a leakage current according to a parasitic capacitance component of the fourth transistor may have opposite polarities, and a current flowing through the second capacitor and a leakage current according to a parasitic capacitance component of the second transistor may have opposite polarities.

According to an embodiment of the present disclosure, a multi-stage amplifier includes a plurality of amplifiers connected in parallel to each other through input nodes and output nodes, and each of the plurality of amplifiers includes a first transistor and a second transistor to which differential input signals respectively applied to the input nodes are applied to gate terminals thereof, respectively, a second transistor having one end connected to the first transistor, a gate terminal receiving a first bias signal, and a second end connected to one of the output nodes which outputs one of differential output signals of a differential output signal pair, a fourth transistor having a first end connected to the second transistor, a gate terminal receiving a second bias signal, and having a second end connected to the second one of the output nodes which outputs the other one of the differential output signals, and a pair of capacitors coupled to the second transistor and the fourth transistor, and having a cross-coupled structure with respect to each other.

According to an embodiment of the present disclosure, a wireless communication device includes a processor, and a radio frequency (RF) chip that generates an RF signal based on a baseband signal received from the processor, and adjusts a gain of the RF signal through an amplifier to output an adjusted RF signal, and the amplifier includes a first transistor and a second transistor to which the RF signal is applied to respective gate terminals, a second transistor having a first end connected to the first transistor, a gate terminal receiving a second bias signal, and a second end outputting one of differential output signals of a differential output signal pair, a fourth transistor having a first end connected to the second transistor, a gate terminal receiving a second bias signal, and having a second end outputting the other one of the differential output signals, and a pair of capacitors coupled to the second transistor and the fourth transistor, and having a cross-coupled structure with respect to each other.

### BRIEF DESCRIPTION OF THE FIGURES

A brief description of each drawing is provided to facilitate a more thorough understanding of the drawings referenced in the detailed description of the present disclosure.

FIG. 1 is a circuit diagram of an amplifier, according to an embodiment of the present disclosure.

FIG. 2 illustrates parasitic capacitance components of an amplifier.

FIGS. 3A and 3B illustrate leakage paths according to parasitic capacitance components of FIG. 2 and cancellation paths according to a pair of capacitors.

FIG. 4 is a circuit diagram of an amplifier, according to an embodiment of the present disclosure.

FIGS. 5A and 5B illustrate output impedance characteristics of an amplifier, according to an embodiment of the present disclosure.

FIG. 6 illustrates a k-factor of an amplifier, according to an embodiment of the present disclosure.

FIG. 7 illustrates isolation characteristics of an amplifier, according to an embodiment of the present disclosure.

FIG. 8 is a circuit diagram of a multi-stage amplifier, according to an embodiment of the present disclosure.

FIG. 9 illustrates a dynamic range of an output of a multi-stage amplifier, according to an embodiment of the present disclosure.

FIG. 10 illustrates a wireless communication device, according to an embodiment of the present disclosure.

FIG. 11 illustrates an embodiment of an RF chip of FIG. 10.

### DETAILED DESCRIPTION

Hereinafter, embodiments of the present disclosure may be described in detail and clearly to such an extent that one of ordinary skill in the art can readily implement the disclosed embodiments as well as other embodiments.

Herein, a “first end” of a field effect transistor (FET) is a source or a drain, and a “second end” or “opposite end” or the like is a drain or a source, respectively. Thus, if a first end is stated to be a drain, the second end is a source, and vice versa.

In the following description, after an element is introduced with a name followed by a label, the element may subsequently be referred to interchangeably by a shortened version of the name followed by the label, or by just the label. For example, “a first transistor TR1-1” may later be referred to as “transistor TR1-1” or as just “TR1-1”.

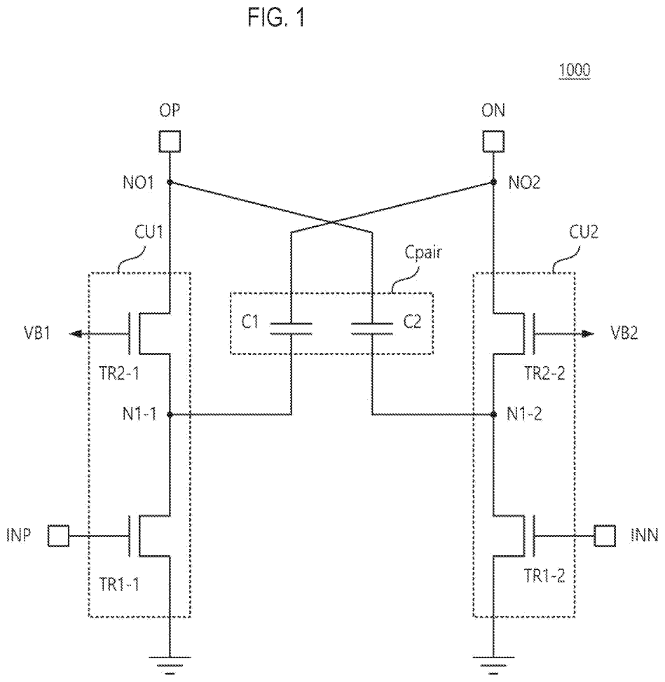

FIG. 1 is a circuit diagram of an amplifier, 1000, according to an embodiment of the present disclosure. The amplifier 1000 includes a first transistor TR1-1, a second transistor TR1-2, a third transistor TR2-1, a fourth transistor TR2-2 (each of which may be FETs), and a pair of capacitors Cpair.

Differential input signals INP and INN may together form a differential signal pair. For instance, considering the reference ground voltage in the amplifier 1000, at any given point in time, if signal INP has a positive voltage referenced to ground, the signal INN has a negative voltage referenced to ground of equal magnitude, and vice versa. Thus, signals INP and INP may be said to have opposite polarities. Input signal INP may be applied to a gate terminal (“gate”) of the first transistor TR1-1 and input signal INN may be applied to the gate of the second transistor TR1-2. Alternatively, the input signals INN are INP applied to the gates of transistors TR1-1 and TR1-2, respectively.

As an example, the differential input signals INP and INN may be an intermediate frequency (IF) signal or a radio frequency (RF) signal, which are obtained by up-converting a baseband signal. As an embodiment, the differential input signals INP and INN may have a frequency range of an FR1 (Frequency Range 1) or an FR2 (Frequency Range 2), which are defined in New Radio (NR). The FR1 may mean “sub 6 GHz range”, and the FR2 may mean “above 6 GHz range” and may be called a millimeter wave (mmW) band. Alternatively, the differential input signals INP and INN may be signals of various other frequency bands.

A first end (the source) of each of transistor TR1-1 and transistor TR1-2 may be commonly grounded. In this regard, transistor TR1-1 and transistor TR1-2 may be common source transistors to which the differential input signals INP and INN are applied to gates thereof and the sources thereof are commonly grounded. In addition, the other end (the drain) of the first transistor TR1-1 may be connected to a first end of the third transistor TR2-1 through a first node N1-1, and the second end of the second transistor TR1-2 may be connected to a first end of the fourth transistor TR2-2 through a second node N1-2.

A differential output signal pair comprising differential output signals OP and ON may be output collectively at second ends of the third and fourth transistors TR2-1 and TR2-2, respectively. The first end of the third transistor TR2-1 may be connected to the first transistor TR1-1. Accordingly, the third transistor TR2-1 may be a (common gate) cascode transistor stacked with the first transistor TR1-1. The third transistor TR2-1 may output differential output signal OP through its second end, which is connected to a first output node N01. A DC bias signal (interchangeably, “control signal” or “operating signal”) VB1 may be applied to the gate of the third transistor TR2-1, and the third transistor TR2-1 may be biased according to the bias signal VB1. Thus, the third transistor TR2-1 may be a common gate transistor to which the bias signal VB1 is applied at its gate and one of the differential output signals, OP, is output at its second end.

The fourth and second transistors TR2-2 and TR1-2 are connected in a cascode configuration in which a first end of the fourth transistor TR2-2 is connected to the drain of the second transistor TR1-2 (and thus the fourth transistor TR2-2 may be referred to as a cascode transistor). Furth transistor TR2-2 may output the other differential output signal, ON, through its second end which is connected to a second output node NO2. A bias signal VB2 may be applied to the gate of the fourth transistor TR2-2, and as in the above description, transistor TR2-2 may be biased according to the bias signal VB2. Thus, the fourth transistor TR2-2 may be a common gate transistor to which the bias signal VB2 is applied to the gate thereof and the differential output signal ON is output at its second end.

Like the differential input signals INP and INN, the differential output signals OP and ON have opposite polarities. For instance, at any given time, when the signal OP has a positive voltage relative to the ground voltage, signal ON may have a negative voltage of equal magnitude, and vice versa. It is noted here that in an alternative example, signal ON is output at node NO1 and signal OP is output at node NO2.

As described above, since the first transistor TR1-1 and the third transistor TR2-1 are connected in a cascode configuration, they may be together referred to as a first cascode unit CU1, and since the second transistor TR1-2 and the fourth transistor TR2-2 are also connected in a cascode configuration, they may be together referred to as a second cascode unit CU2.

The first cascode unit CU1 amplifies the first differential input signal INP and outputs the first differential output signal OP, and the second cascode unit CU2 amplifies the second differential input signal INN and outputs the second differential output signal ON. In an embodiment, when each of the first transistor TR1-1 and second transistor TR1-2 is turned on (e.g., operating in a saturation mode), the differential input signals INP and INN may be amplified, and the amplified signals INP and INN may be transferred to the third transistor TR2-1 and the fourth transistor TR2-2, respectively. In addition, each of the first cascode unit CU1 and the second cascode unit CU2 may be turned on or turned off according to a gate voltage of each transistor included in the first cascode unit CU1 and the second cascode unit CU2.

In an embodiment, a size of the third transistor TR2-1 may be designed to be greater than that of the first transistor TR1-1, and a size of the fourth transistor TR2-2 may be designed to be greater than that of the second transistor TR1-2. Accordingly, a desired voltage headroom of the differential output signals OP and ON of the amplifier 1000 may be secured. However, the possibility of oscillation of the amplifier 1000 arises as a trade-off with securing the voltage headroom. In this regard, a negative component may occur in an output impedance defined at the second end (at the first output node NO1) of third transistor TR2-1 and the second end (at the second output node NO2) of the fourth transistor TR2-2. Accordingly, cascode amplifier 1000 may include the pair of capacitors Cpair (comprising capacitors C1 and C2) connected to the first and second cascode units CU1 and CU2 to cancel the negative component.

The pair of capacitors Cpair are coupled to the third transistor TR2-1 and the fourth transistor TR2-2, and may have a differential cross-coupled structure with respect to each other. The pair of capacitors Cpair may include first capacitor C1 and second capacitor C2 having a cross-coupled structure with respect to each other.

The first capacitor C1 has a first end connected to the second end of fourth transistor TR2-2 and a second end connected to the first end of third transistor TR2-1. The second capacitor C2 has a first end connected to the second end of third transistor TR2-1 and a second end connected to the first end of fourth transistor TR2-2. It may be understood that the first capacitor C1 and the second capacitor C2 have the cross-coupled structure with respect to each other and are coupled to the first cascode unit CU1 and the second cascode unit CU2. As a result, a parasitic capacitance component of third transistor TR2-1 and a parasitic capacitance component of fourth transistor TR2-2 may be canceled out. To this end, the first capacitor C1 may cancel the parasitic capacitance component of fourth transistor TR2-2, and the second capacitor C2 may cancel the parasitic capacitance component of third transistor TR2-1.

According to the above-described embodiment, when sizes of third transistor TR2-1 and fourth transistor TR2-2 are designed to be greater than sizes of the first and second transistors TR1-1 and TR1-2, parasitic capacitance components of the third and fourth transistors TR2-1 and TR2-2 increase. An increase in the parasitic capacitance component causes a negative component of the output impedance, which means that an S-parameter S12 (representing insertion loss from output to input) of the amplifier 1000 increases. In addition, the possibility of oscillation in the amplifier 1000 arises due to the negative component of the output impedance. In addition, since leakage occurs due to the parasitic capacitance component even when the amplifier 1000 is in an off state, isolation performance between inputs and outputs may be degraded.

However, these deleterious effects are eliminated or reduced with the configuration of amplifier 1000 having the pair of capacitors Cpair with a cross-coupled structure. This is because the parasitic capacitance components are canceled or substantially canceled, so that the negative component of the output impedance defined at the second end of third transistor TR2-1 and the second end of the fourth transistor TR2-2 may be canceled. As a result, the resistance component of the output impedance may have a positive value.

In an embodiment, the capacitance of the first capacitor C1 and the capacitance of the second capacitor C2 may be capacitance values that cause the parasitic capacitance components to be canceled. Since the parasitic capacitance components increase according to the size of third transistor TR2-1 and the size of second transistor TR2-2, during a design stage, the capacitance of the pair of capacitors Cpair may be adjusted according to the sizes of third and fourth transistors TR2-1 and TR2-2. For example, the capacitance of the first capacitor C1 may be set according to the size of fourth transistor TR2-2, and the capacitance of the second capacitor C2 may be set according to the size of third transistor TR2-1.

The parasitic capacitance component may occur not only when the amplifier 1000 performs an amplification operation in an on state (e.g., the saturation state) but also when the amplifier 1000 is in an off state. However, the pair of capacitors Cpair according to an embodiment may cancel the parasitic capacitance components generated when the first through fourth transistors TR1-1, transistor TR1-2, TR2-1, and TR2-2 are turned on and turned off.

In the present disclosure according to the above-described embodiments, the parasitic capacitance component of each common gate transistor included in the cascode amplifier 1000 may be canceled by connecting the capacitors having a cross-coupled structure to the cascode amplifier 1000. Accordingly, the amplifier 1000 according to the present disclosure may eliminate the possibility of oscillation by removing the negative component of the output impedance, and may improve the isolation performance between inputs (the gates of the common source transistors) and outputs (the second ends of the common gate transistors) in the off state.

Hereinafter, various embodiments of the above-described amplifier 1000 will be described.

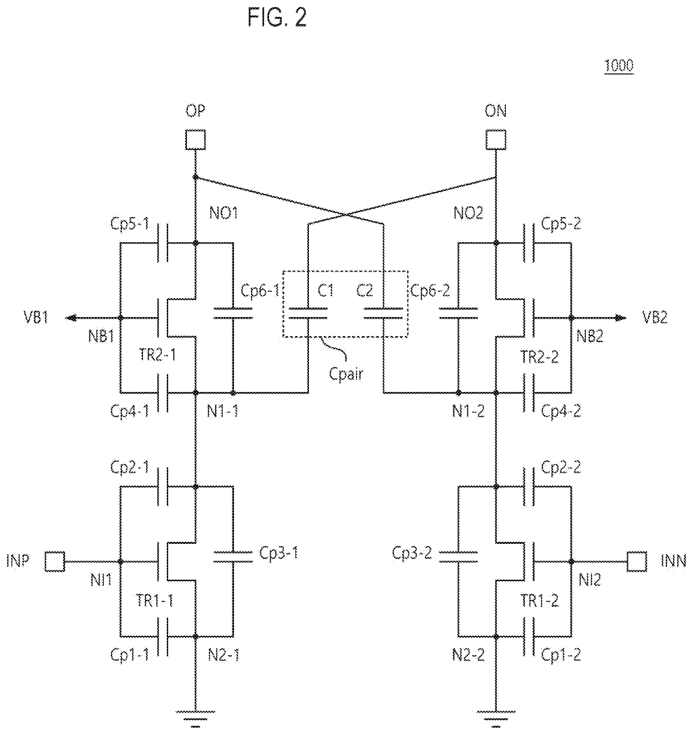

FIG. 2 illustrates parasitic capacitance components of an amplifier.

Referring to FIG. 2, in the transistors included in the amplifier 1000 according to an embodiment, parasitic capacitances may exist between the gate and the second end, between the gate and the first end, and between the first and second ends.

For example, a parasitic capacitance Cp1-1 may exist between a first input node NI1 connected to the gate of the first transistor TR1-1 and a node N2-1 connected to the second end of the first transistor TR1-1, a parasitic capacitance Cp2-1 may exist between the first input node NI1 and the node N1-1, and a parasitic capacitance Cp3-1 may exist between the node N1-1 and the node N2-1.

For example, a parasitic capacitance Cp1-2 may exist between a second input node NI2 connected to the gate terminal of transistor TR1-2 and a node N2-2 connected to the second end of transistor TR1-2, a parasitic capacitance Cp2-2 may exist between the second input node NI2 and the node N1-2, and a parasitic capacitance Cp3-2 may exist between the node N1-2 and the node N2-2.

For example, a parasitic capacitance Cp4-1 may exist between a first bias node NB1 connected to the gate terminal of transistor TR2-1 and the node N1-1, a parasitic capacitance Cp5-1 may exist between the first bias node NB1 and the first output node N01, and a parasitic capacitance Cp6-1 may exist between the first output node NO1 and the first node N1-1.

For example, a parasitic capacitance Cp4-2 may exist between a second bias node NB2 connected to the gate terminal of transistor TR2-2 and the node N1-2, a parasitic capacitance Cp5-2 may exist between the second bias node NB2 and the second output node NO2, and a parasitic capacitance Cp6-2 may exist between the second output node NO2 and the node N1-2.

In particular, as the sizes of the third transistor TR2-1 and the fourth transistor TR2-2, which are common gate transistors, are increased to secure the output headroom, the parasitic capacitance components increase according to the associated parasitic capacitances (the parasitic capacitances Cp4-1, Cp5-1, Cp6-1, Cp4-2, Cp5-2, and Cp6-2). The increase in the parasitic capacitance component may result in performance deterioration (e.g., increased oscillation possibility, isolation performance, etc.) of the amplifier 1000.

In addition, the parasitic capacitance components may also affect performance degradation, according to the parasitic capacitances (the parasitic capacitances Cp1-1, Cp2-1, Cp3-1, Cp1-2, Cp2-2, Cp3-2) associated with the first transistor TR1-1 and second transistor TR1-2 which are common source transistors.

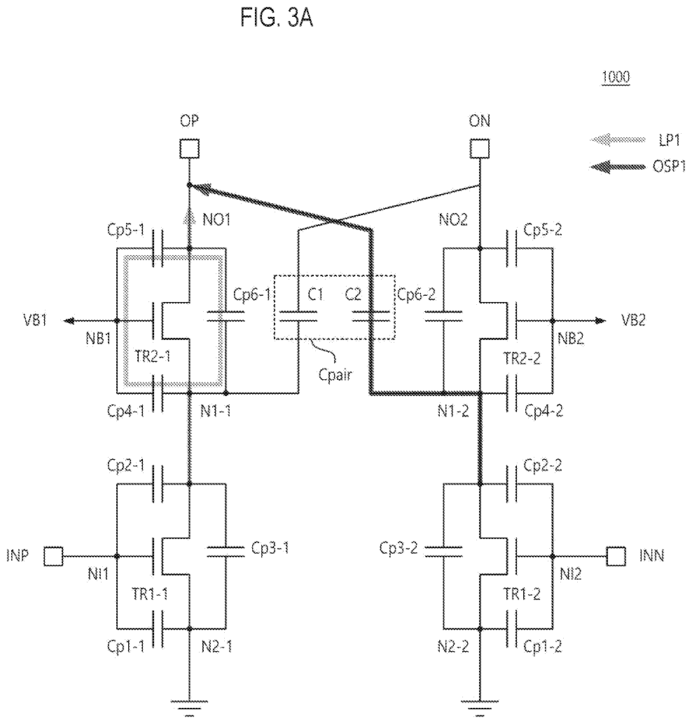

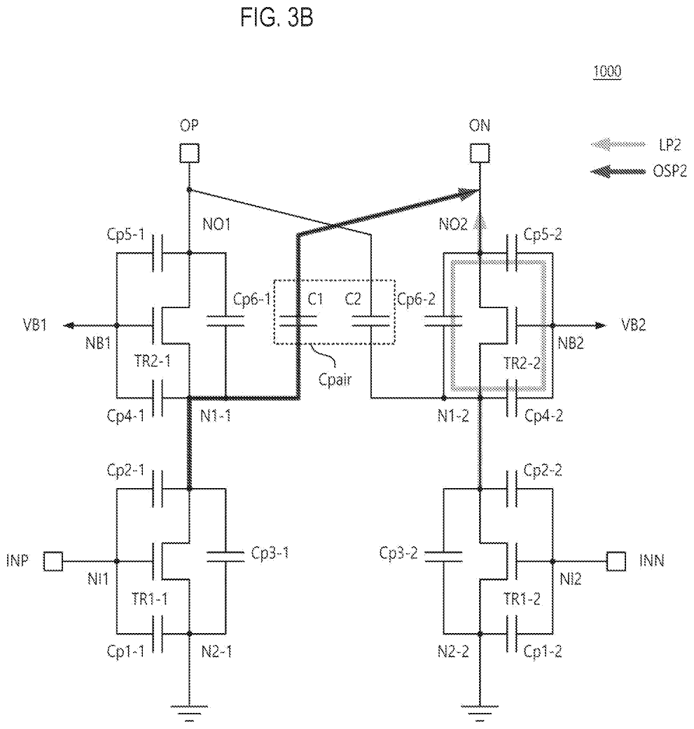

FIGS. 3A and 3B illustrate leakage paths according to parasitic capacitance components of FIG. 2 and cancellation paths according to a pair of capacitors.

Referring first to FIG. 3A, when the amplifier 1000 performs differential operation, a first leakage path LP1 including the parasitic capacitances Cp4-1, Cp5-1, and Cp6-1 with respect to the first input component INP may be defined. The leakage current flowing through the first leakage path LP1 may include a leakage current according to a parasitic capacitance component of the first transistor TR1-1. When the leakage current flowing through the first leakage path LP1 cannot be canceled out, a negative component may occur in the output impedance defined at the first output node N01.

However, in embodiments of the present disclosure, a first offset path OSP1 including the second capacitor C2 may be defined. The first leakage path LP1 and the first offset path OSP1 are commonly connected to the first output node N01. The current flowing through the second capacitor C2 (i.e., the current flowing through the first offset path OSP1) may have a polarity opposite to that of the leakage current (i.e., the current flowing through the first leakage path LP1) according to the parasitic capacitance component of third transistor TR2-1. Accordingly, the leakage current according to the first leakage path LP1 may be canceled through the leakage current according to the first offset path OSP1.

Likewise, referring to FIG. 3B, when the amplifier 1000 performs differential operation, a second leakage path LP2 including the parasitic capacitances Cp4-2, Cp5-2, and Cp6-2 with respect to the second input component INN may be defined. The leakage current flowing through the second leakage path LP2 may include a leakage current according to a parasitic capacitance component of second transistor TR1-2. When the leakage current flowing through the second leakage path LP2 cannot be canceled out, a negative component may occur in the output impedance defined at the second output node NO2.

However, in embodiments of the present disclosure, a second offset path OSP2 including the first capacitor C1 may be defined. The second leakage path LP2 and the second offset path OSP2 are commonly connected to the second output node NO2. The current flowing through the first capacitor C1 (i.e., the current flowing through the second offset path OSP2) may have a polarity opposite to that of the leakage current (i.e., the current flowing through the second leakage path LP2) according to the parasitic capacitance component of fourth transistor TR2-2. Accordingly, the leakage current according to the second leakage path LP2 may be canceled through the leakage current according to the second offset path OSP2.

According to the above-described embodiment, the cascode amplifier 1000 may cancel its parasitic capacitance component and the resulting leakage current through the pair of capacitors Cpair. Since the leakage current is due to the parasitic capacitance component, cascode amplifier 1000 may form the offset path through the capacitor pair and may cancel the leakage current in terms of polarity.

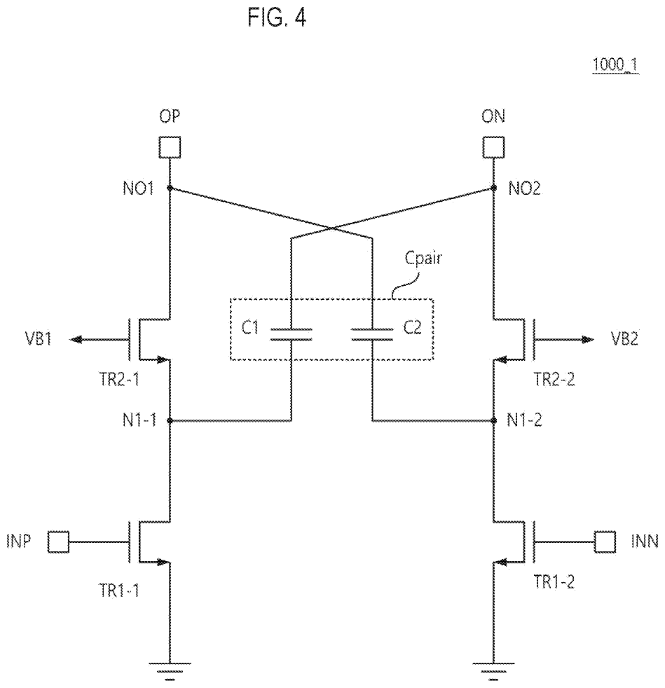

FIG. 4 is a circuit diagram of an amplifier, 1000_1, according to an embodiment of the present disclosure. Hereinafter, additional descriptions of overlapping parts with those described above will be omitted to avoid redundancy.

Referring to FIG. 4, the first transistor TR1-1, transistor TR1-2, transistor TR2-1, and transistor TR2-2 included in amplifier 1000_1 may be n-type metal-oxide-semiconductor field-effect transistors (NMOS FETs).

The first transistor TR1-1 may have a gate to which one of the differential input signals INP and INN is applied, a source terminal (“source”) connected to ground, and a drain connected to a source of transistor TR2-1. Since the drain of the first transistor TR1-1 is connected to the source of transistor TR2-1 through the first node N1-1, the first transistor TR1-1 and transistor TR2-1 may have a cascode structure.

The second transistor TR1-2 may have a gate to which the other of the differential input signals INP and INN is applied, a source connected to ground, and a drain connected to a source of transistor TR2-2. Since the drain of the second transistor TR1-2 is connected to the source of the fourth transistor TR2-2 through the node N1-2, transistor TR1-2 and transistor TR2-2 may have a cascode structure.

The third transistor TR2-1 may have a source connected to the first transistor TR1-1, a gate to which the bias signal VB1 is applied, and a drain connected to the first output node N01.

The transistor TR2-2 may have a source connected to transistor TR1-2, a gate to which the bias signal VB2 is applied, and a drain connected to the second output node NO2.

Alternatively, in other embodiments, at least one among the first transistor TR1-1, second transistor TR1-2, the third transistor TR2-1, and the fourth transistor TR2-2 may be an NMOS FET, and at least one among the first transistor TR1-1, transistor TR1-2, transistor TR2-1, and the fourth transistor TR2-2 may be a p-type metal-oxide-semiconductor field-effect transistor (“PFET” or PMOS FET).

The first capacitor C1 of the pair of capacitors Cpair may have one end connected to the drain of transistor TR2-2 and a second end connected to the source of transistor TR2-1.

The second capacitor C2 of the pair of capacitors Cpair may have one end connected to the drain of transistor TR2-1 and a second end connected to the source of transistor TR2-2.

The pair of capacitors Cpair may cancel the parasitic capacitance components of transistor TR2-1 and transistor TR2-2. For example, the first capacitor C1 may cancel the leakage current flowing through the node N1-2 and the second output node NO2 according to the parasitic capacitance component of transistor TR2-2. For example, the second capacitor C2 may cancel the leakage current flowing through the first node N1-1 and the first output node NO1 according to the parasitic capacitance component of transistor TR2-1.

The amplifier 1000_1 according to the above-described embodiments may be implemented based on various complementary metal oxide semiconductor (CMOS) processes. Accordingly, the amplifier 1000_1 may be integrated into a single chip. In addition, the amplifier 1000_1 may overcome the disadvantages (linearity, efficiency, etc.) of the CMOS process through the cascode structure.

Hereinafter, various characteristics of an amplifier according to embodiments of the present disclosure will be described. The characteristics of the amplifier will be described by comparing the amplifier of the present disclosure with the pair of capacitors Cpair and an amplifier (hereinafter referred to as a comparison reference amplifier) without the pair of capacitors Cpair.

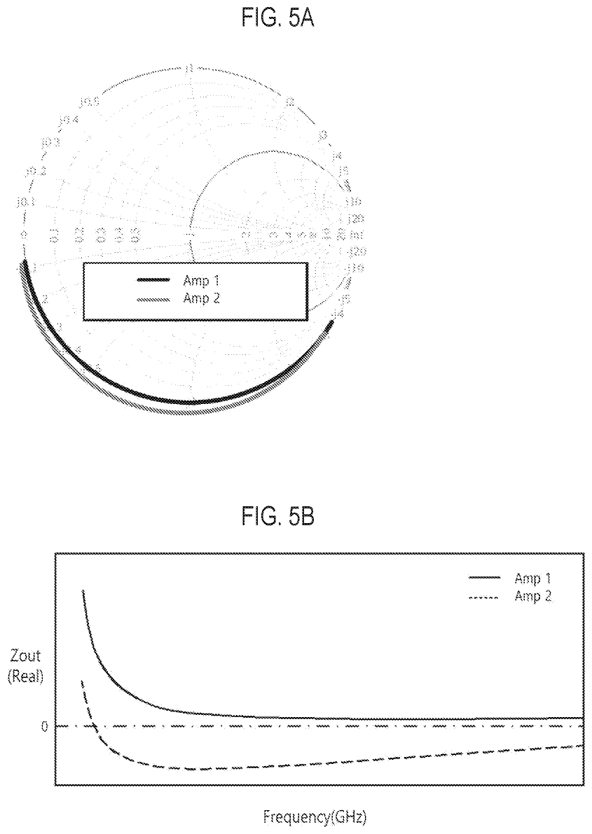

FIGS. 5A and 5B illustrate output impedance characteristics of an amplifier, according to an embodiment of the present disclosure.

Output impedance characteristics may be illustrated through a Smith chart. In this case, the output impedance may be an impedance viewed from the output end (e.g., the first output node NO1 and the second output node NO2 described above) of the amplifier.

Referring first to FIG. 5A, the comparison reference amplifier Amp 2 does not have the pair of capacitors Cpair, so a negative component is generated in the output impedance due to the parasitic capacitance component. Thus, the output impedance is defined at or near an outer boundary of the Smith chart. In contrast, in the amplifier Amp 1 of the present disclosure, since the parasitic capacitance component may be canceled through the pair of capacitors Cpair, the negative component of the output impedance may be removed. Therefore, the output impedance may be defined closer to the center of the Smith chart.

Removal/non-removal of the negative component of the output impedance may be illustrated in FIG. 5B. FIG. 5B illustrates the resistance component (the real part) of the output impedance. Unlike the comparison reference amplifier Amp 2 in which the negative component is generated in the real part, in the amplifier Amp 1 of the present disclosure, the graph of FIG. 5B illustrates that the negative component of the output impedance is removed at frequencies of interest.

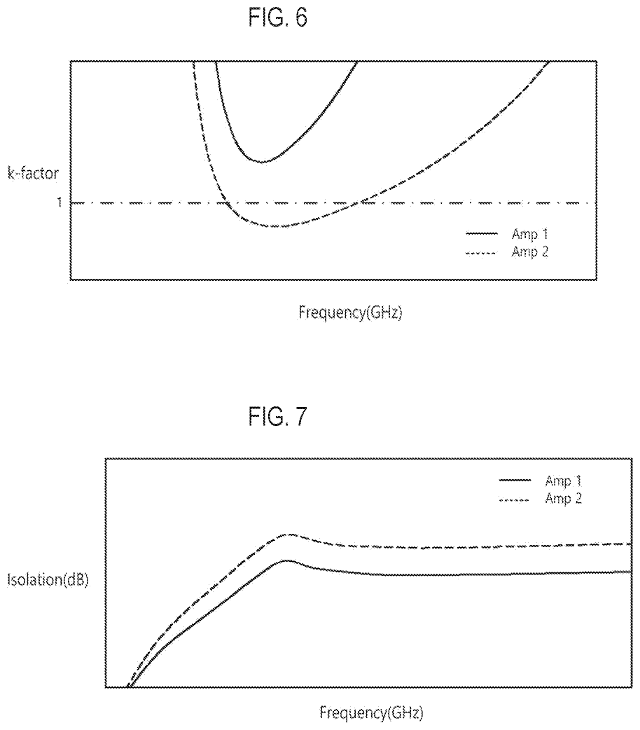

FIG. 6 illustrates a k-factor of an amplifier, according to an embodiment of the present disclosure. The k-factor refers to the oscillation possibility of the amplifier and is defined based on an S-parameter. For example, as the parameter S12 increases, the k-factor becomes lower than 1, which means that the possibility of oscillation of the amplifier increases. In other words, a k-factor lower than 1 means that S12 performance has deteriorated.

In the case of the comparison reference amplifier Amp 2, there are bands in which the k-factor is less than 1 in some bands. That is, the comparison reference amplifier Amp 2 has the possibility of oscillation as S12 performance deteriorates. In contrast, in the case of the amplifier Amp 1 of the present disclosure, it is seen that the k-factor is greater than 1 in all bands of interest. In other words, the amplifier Amp 1 of the present disclosure may eliminate the possibility of oscillation as the performance of S12 is improved. In addition, since the possibility of oscillation is eliminated in the amplifier Amp 1 of the present disclosure despite the larger size of the common gate transistors relative to the common source transistors, multiple advantages (e.g., increased output linearity and reduced possibility of oscillation) may be obtained together in association with the larger sizes of the common gate transistors.

FIG. 7 illustrates isolation characteristics of an amplifier, according to an embodiment of the present disclosure.

Referring to FIG. 7, even when the amplifier is turned off as described above, when the size of the common gate transistor increases, the influence of the leakage current due to the parasitic capacitance component increases.

Therefore, it may be seen that the isolation characteristic between inputs and outputs is relatively improved as the amplifier Amp 1 of the present disclosure cancels out the parasitic capacitance components, compared to the comparison reference amplifier Amp 2 that cannot cancel the parasitic capacitance components. In particular, the amplifier Amp 1 of the present disclosure may have improved isolation characteristics compared to the comparison reference amplifier Amp 2 in all bands of interest during the off state.

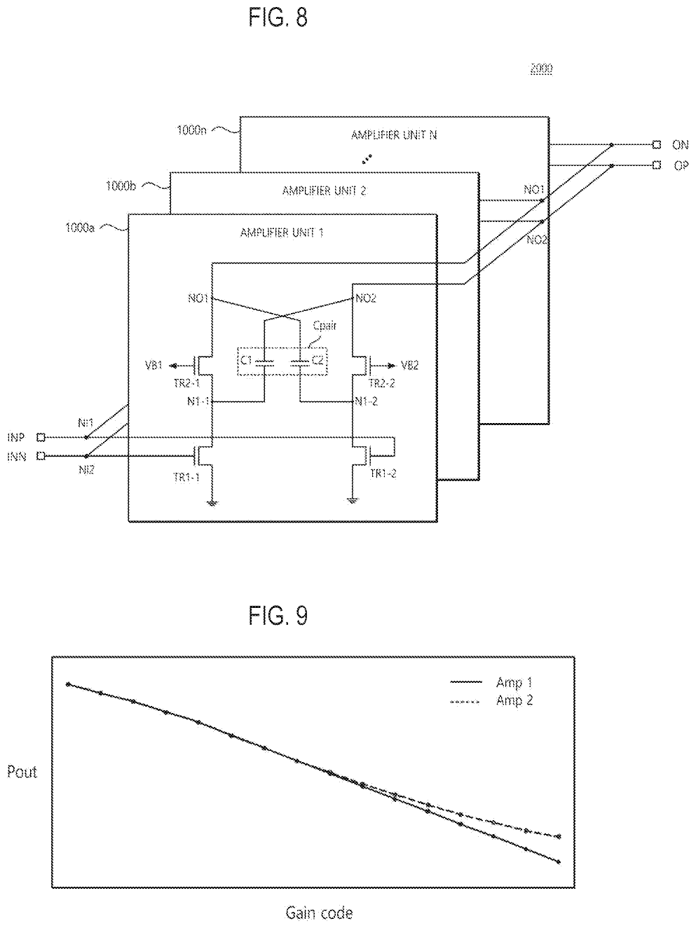

FIG. 8 is a circuit diagram of a multi-stage amplifier, 2000, according to an embodiment of the present disclosure.

Referring to FIG. 8, a multi-stage amplifier 2000 according to an embodiment may include a plurality of amplifiers 1000a, and 1000b to 1000n.

The plurality of amplifiers 1000a, and 1000b to 1000n may be connected in parallel with each other through input nodes (the first input node NI1 and the second input node NI2) and output nodes (the first output node NO1 and the second output node NO2). Accordingly, common differential input signals INP and INN may be applied to all of the plurality of amplifiers 1000a, and 1000b to 1000n, and the differential output signals OP and ON may be output through common output nodes.

Each of the plurality of amplifiers 1000a, and 1000b to 1000n may be implemented according to the above-described embodiments. In an embodiment, each of amplifiers 1000a to 1000n may include a first transistor TR1-1, a second transistor TR1-2, a third transistor TR2-1, a fourth transistor TR2-2, and a pair of capacitors Cpair. The differential input signals INP and INN respectively applied through input nodes may be respectively applied to gates of the first transistor TR1-1 and the second transistor TR1-2. transistor TR2-1 may have a first end connected to the first transistor TR1-1, a gate receiving the first bias signal VB1, and a second end connected to the first output node NO1 for outputting one of the differential output signals OP and ON. The fourth transistor TR2-2 may have a first end connected to the second transistor TR1-2, a gate receiving the second bias signal VB2, and a second end connected to the second output node NO2 for outputting the other one of the differential output signals OP and ON. The pair of capacitors Cpair are coupled to the third transistor TR2-1 and the fourth transistor TR2-2, and may have a differential cross-coupled structure with respect to each other.

In each of the amplifiers 1000a to 1000n, the parasitic capacitance components may be removed through the pair of capacitors Cpair according to the above-described embodiments.

Each of the amplifiers 1000a to 1000n may be controlled by the bias signals VB1 and VB2. For example, the bias signals VB1 and VB2 may be digital control signals and may turn on or off at least one of the amplifiers 1000a to 1000n.

When the first transistor TR1-1, transistor TR1-2, transistor TR2-1, and transistor TR2-2 included in at least one amplifier according to the operating signals VB1 and VB2 are turned off, a leakage current may occur when a parasitic capacitance component is generated. However, the pair of capacitors Cpair included in the multi-stage amplifier 2000 of the present disclosure may cancel parasitic capacitance components when turned off.

The differential output signals OP and ON of the multi-stage amplifier 2000 may have a dynamic range. A single amplifier also has a dynamic range, but for convenience of description, the dynamic range will be described in terms of the multi-stage amplifier 2000 in the present disclosure. The differential output signals OP and ON of the multi-stage amplifier 2000 may have a desired output level within a dynamic range according to a frequency band in which the multi-stage amplifier 2000 operates.

As an embodiment, the multi-stage amplifier 2000 may operate based on “slicing” (selective turn-on and turn-off of individual amplifiers among amplifiers 1000a to 1000n) according to the bias signals VB1 and VB2 in a high gain mode or a low gain mode. In the high gain mode, the multi-stage amplifier 2000 may operate to turn on more amplifiers among the plurality of amplifiers 1000a, and 1000b to 1000n according to the bias signals VB1 and VB2. In the low gain mode, the multi-stage amplifier 2000 may operate to turn off more amplifiers among the plurality of amplifiers 1000a, and 1000b to 1000n according to the bias signals VB1 and VB2.

In the high gain mode or the low gain mode, a leakage current may occur due to a parasitic capacitance component, which may be particularly noticeable in the low gain mode in which relatively more amplifiers are turned off. Due to the influence of such leakage current, dynamic range characteristics may be deteriorated.

However, since the amplifier according to embodiments of the present disclosure may cancel the parasitic capacitance components through the pair of capacitors Cpair in the low gain mode as well as the high gain mode, dynamic range characteristics under all gain conditions (in particular, low gain mode) may be improved.

FIG. 9 illustrates a dynamic range of an output of a multi-stage amplifier, according to an embodiment of the present disclosure.

Referring to FIG. 9, the gain of the multi-stage amplifier Amp 1 (e.g., amplifier 2000) according to an embodiment may be adjusted as at least one of the plurality of amplifiers is turned on or off depending on the bias signals VB1 and VB2. In the case of FIG. 9, a situation in which the amplifier is gradually operated in the low gain mode is illustrated according to gain codes corresponding to the bias signals VB1 and VB2.

In the case of the comparison reference amplifier Amp 2, it may be seen that gain step characteristics are particularly deteriorated as the gain is lowered. In contrast, in the case of the amplifier Amp 1 of the present disclosure, it may be seen that the gain step characteristics are not deteriorated and the output is relatively uniform even in the low gain mode. Accordingly, the dynamic range of the output of the amplifier of the present disclosure may also be improved.

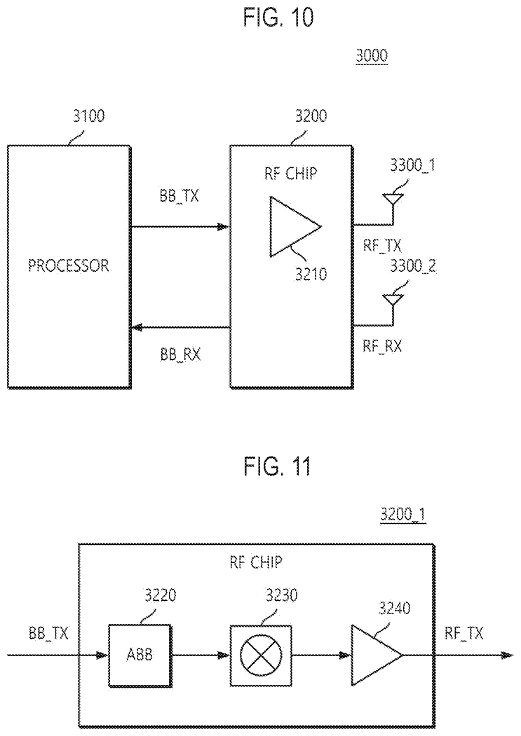

FIG. 10 illustrates a wireless communication device, 3000, according to an embodiment of the present disclosure. The wireless communication device 3000 includes a processor 3100, an RF chip 3200, and antennas 3300_1 and 3300_2.

The processor 3100 may process a digital signal and may convert the digital signal into an analog signal. Alternatively, a modem may convert and process the analog signal into the digital signal. The analog signal that is converted, or is to be converted, may be a baseband signal. The processor 3100 may transfer a baseband transmission signal BB_TX to the RF chip 3200 or may receive and process a baseband reception signal BB_RX from the RF chip 3200. The processor 3100 may be, for example, a modem, an application processor (AP), or a ModAP in which functions of a modem are integrated into an AP.

The RF chip 3200 may up-convert the baseband transmission signal BB_TX received from the processor 3100 and may output an RF transmission signal RF_TX to the antennas 3300_1 and 3300_2, and/or the RF chip 3200 may down-convert the RF reception signal RF_RX received from the antennas 3300_1 and 3300_2 and may output the baseband reception signal BB_RX to the processor 3100.

The RF chip 3200 may include an amplifier 3210 to output the RF transmission signal RF_TX corresponding to a designed gain. The gain may be set for each frequency band supported by the wireless communication device 3000 according to various embodiments. The amplifier 3210 may be implemented according to various embodiments described above.

For example, the amplifier 3210 may be implemented as the amplifier 3210 (e.g., the amplifier 1000 or 2000 described above) having a cascode structure in which a common source transistor and a common gate transistor are connected, and the pair of capacitors Cpair having a cross-coupled structure with respect to each other may be coupled to the common gate transistors included in the cascode structure. The pair of capacitors Cpair may cancel the parasitic capacitance components generated as the size of the common gate transistor increases to secure the headroom of the RF transmission signal RF_TX according to the above-described embodiments.

For example, when the amplifier 3210 is implemented as the multi-stage amplifier 2000 including the plurality of amplifiers 1000a to 1000n, at least one of the plurality of amplifiers 1000a to 1000n may be turned on and off according to the operating signals VB1 and VB2, and accordingly, the gain of the RF transmission signal RF_TX to be transmitted may be adjusted.

For example, when the RF transmission signal RF_TX has a relatively low gain as the RF chip 3200 operates in a low gain mode, among the plurality of amplifiers 1000a to 1000n, a relatively large number of amplifiers 1000 are in an off state, and thus the influence of the parasitic capacitance component may increase. Nevertheless, the amplifier 3210 may cancel the parasitic capacitance components through the pair of capacitors Cpair to remove the negative component of the output impedance even in the low gain mode and to improve the dynamic range performance of the amplifier 3210.

The antennas 3300_1 and 3300_2 may transmit the RF transmission signal RF_TX received from the RF chip 3200 to another wireless communication device 3000, and/or may transfer the RF reception signal RF_RX received from the other wireless communication device 3000 to the RF chip 3200.

FIG. 11 illustrates an embodiment of an RF chip of FIG. 10.

Referring to FIG. 11, an RF chip 3200_1 according to an embodiment may be an RF chip for transmission, and includes an analog baseband (ABB) chip 3220, a mixer 3230, and an amplifier 3240.

The ABB chip 3220 may process the baseband transmission signal BB_TX received from the processor 3100 in baseband. For example, the ABB chip 3220 may buffer the baseband transmission signal BB_TX, may filter a signal of a specific band from the baseband signal, and/or may perform various other operations.

The mixer 3230 may up-convert the frequency of the signal processed through the ABB chip 3220. For example, the mixer 3230 may up-convert the frequency of the processed signal from baseband to an RF band to be transmitted.

The amplifier 3240 may amplify the signal up-converted to the RF band according to a designed gain. The amplifier 3240 may be implemented according to embodiments described above. For example, the amplifier 3240 may be implemented as the amplifier 3210 just described, having a cascode structure in which a common source transistor and a common gate transistor are connected, and the pair of capacitors Cpair having a cross-coupled structure with respect to each other may be coupled to the common gate transistors included in the cascode structure.

According to an embodiment of the present disclosure, even if sizes of the common gate transistors are larger than the common source transistors in a cascode amplifier, the cascode amplifier having improved amplification characteristics may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An amplifier comprising:
a first transistor and a second transistor to which differential input signals of a differential input signal pair are applied to gate terminals thereof, respectively;
a third transistor having a first end connected to the first transistor, a gate terminal receiving a bias signal, and a second end outputting a first differential output signal of a differential output signal pair;
a fourth transistor having a first end connected to the second transistor, a gate terminal receiving a second bias signal, and a second end outputting a second differential output signal of the differential output signal pair; and
a pair of capacitors coupled to the third transistor and the fourth transistor, and having a cross-coupled structure with respect to each other.

2. The amplifier of claim 1, wherein the pair of capacitors includes:
a first capacitor having a first end connected to the second end of the fourth transistor and having a second end connected to the first end of the third transistor; and
a second capacitor having a first end connected to the second end of the third transistor and a second end connected to the first end of the fourth transistor.

3. The amplifier of claim 2, wherein:
the first capacitor cancels a parasitic capacitance component of the fourth transistor, and
the second capacitor cancels a parasitic capacitance component of the third transistor.

4. The amplifier of claim 2, wherein a capacitance of the first capacitor has a value depending on a size of the fourth transistor, and
wherein a capacitance of the second capacitor has a value depending on a size of the third transistor.

5. The amplifier of claim 1, wherein a resistance component of an output impedance defined at the other end of the third transistor and the other end of the fourth transistor has a positive value.

6. The amplifier of claim 1, wherein:
the pair of capacitors cancels parasitic capacitance components of the third and fourth transistors when the first through fourth transistors are turned on; and
the pair of capacitors cancels parasitic capacitance components of the third and fourth transistors when the first through fourth transistors are turned off.

7. The amplifier of claim 1, wherein the first through fourth transistors are each an NMOS transistor.

8. The amplifier of claim 7, wherein:
a first end of a first capacitor of the pair of capacitors is connected to a drain of the fourth transistor and the other end of the first capacitor is connected to a source of the third transistor, and
a first end of a second capacitor of the pair of capacitors is connected to a drain of the third transistor and the other end of the second capacitor is connected to a source of the fourth transistor.

9. The amplifier of claim 7, wherein:
a drain of the first transistor is connected to a source of the third transistor, and
a drain terminal of the second transistor is connected to a source of the fourth transistor.

10. The amplifier of claim 1, wherein a size of the third transistor is greater than that of the first transistor, and
a size of the fourth transistor is greater than that of the second transistor.

11. The amplifier of claim 3, wherein a current flowing through the first capacitor and a leakage current according to a parasitic capacitance component of the fourth transistor have opposite polarities, and
a current flowing through the second capacitor and a leakage current according to a parasitic capacitance component of the third transistor have opposite polarities.

12. A multi-stage amplifier comprising:
a plurality of amplifiers connected in parallel to each other through input nodes and output nodes, and
wherein each of the plurality of amplifiers includes:
a first transistor and a second transistor to which differential input signals of a differential input signal pair, which are respectively applied to the input nodes, are applied to gate terminals thereof, respectively;
a third transistor having a first end connected to the first transistor, a gate terminal receiving a first bias signal, and a second end, connected to a first one of the output nodes, which outputs a first differential output signal of a differential output signal pair;
a fourth transistor having a first end connected to the second transistor, a gate terminal receiving a second bias signal, and a second end connected to a second one of the output nodes, which outputs a second differential output signal of the differential output signal pair; and
a pair of capacitors coupled to the third transistor and the fourth transistor, and having a cross-coupled structure with respect to each other.

13. The multi-stage amplifier of claim 12, wherein the pair of capacitors includes:
a first capacitor having a first end connected to the second end of the third transistor and having a second end connected to the first end of the fourth transistor; and
a second capacitor having a first end connected to the second end of the fourth transistor and having a second end connected to the first end of the third transistor.

14. The multi-stage amplifier of claim 13, wherein the first capacitor cancels a parasitic capacitance component of the fourth transistor, and
wherein the second capacitor cancels a parasitic capacitance component of the third transistor.

15. The multi-stage amplifier of claim 12, wherein each of the first and second bias signals turns on or turns off at least one amplifier among the plurality of amplifiers.

16. The multi-stage amplifier of claim 15, wherein the pair of capacitors cancels parasitic capacitance components generated when the first transistor, the second transistor, the third transistor, and the fourth transistor are turned off according to the first bias signal and/or the second bias signal.

17. The multi-stage amplifier of claim 13, wherein a capacitance of the first capacitor has a value depending on a size of the fourth transistor, and
wherein a capacitance of the second capacitor has a value depending on a size of the third transistor.

18. A wireless communication device comprising:
a processor; and
a radio frequency (RF) chip configured to generate an RF signal based on a baseband signal received from the processor, and to adjust a gain of the RF signal through an amplifier to output an adjusted RF signal, and
wherein the amplifier includes:
a first transistor and a second transistor to which the RF signal is applied to respective gate terminals thereof;
a third transistor having a first end connected to the first transistor, a gate terminal receiving a first bias signal, and a second end outputting a first differential output signal of a differential output signal pair;
a fourth transistor having a first end connected to the second transistor, a gate terminal receiving a second bias signal, and a second end outputting a second differential output signal of the differential output signal pair; and
a pair of capacitors coupled to the third transistor and the fourth transistor, and having a cross-coupled structure with respect to each other.

19. The wireless communication device of claim 18, wherein the pair of capacitors includes:
a first capacitor having one end connected to the second end of the fourth transistor and another end connected to the first end of the third transistor; and
a second capacitor having one end connected to the second end of the third transistor and another end connected to the first end of the fourth transistor, and
wherein the first capacitor cancels a parasitic capacitance component of the fourth transistor, and
wherein the second capacitor cancels a parasitic capacitance component of the third transistor.

20. The wireless communication device of claim 19, wherein a capacitance of the first capacitor has a value depending on a size of the fourth transistor, and
wherein a capacitance of the second capacitor has a value depending on a size of the third transistor.
